(19) United States
(12) Patent Application Publication
(10) Pub. No.: US 2020/0388309 A1
(43) Pub. Date: Dec. 10, 2020

(54) Bitline Precharge Circuitry

(71) Applicant: Arm Limited, Cambridge (GB)

(72) Inventors: Lalit Gupta, Cupertino, CA (US); Gaurav Rattan Singla, San Jose, CA (US); Fakhruddin Ali Bohra, San Jose, CA (US); Shri Sagar Dwivedi, San Jose, CA (US)

(21) Appl. No.: 16/435,425

(22) Filed: Jun. 7, 2019

(51) Int. Cl. G11C 7/12; G11C 7/22

(52) U.S. Cl. CPC G11C 7/12; G11C 7/22

(57) ABSTRACT

Various implementations described herein are directed to a device having an array of bitcells with bitlines coupled to columns of the bitcells. The device may include one or more switch structures that are coupled between the bitlines and a supply voltage, and the switch structures may be configured to precharge the bitlines to the supply voltage when activated. In some instances, the supply voltage may refer to ground or a ground related voltage having a voltage near or equal to zero volts (0V).

### BACKGROUND

This section is intended to provide information relevant to understanding various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In conventional circuit designs, high-density bitcells typically exhibit excessive write-time due to weak passgates. This can limit the cycle-time of memory, and the timing complexity of write-assist can cause write failure at low or high voltage corners. Also, in some instances, operatively precharging bitlines to a high voltage supply (e.g., Vdd) may use a significant portion of overall dynamic power. As such, there exists a need to reduce precharge power so as to reduce the overall dynamic power of memory.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIG. 1 illustrates a diagram of memory circuitry in accordance with various implementations described herein.

FIGS. 2A-2C illustrate various diagrams of the memory circuitry in accordance with various implementations described herein.

FIG. 3 illustrates a process flow diagram of a method for providing memory circuitry in accordance with various implementations described herein.

### DETAILED DESCRIPTION

Various implementations described herein are directed to bitline precharge (or discharge) circuitry including schemes and techniques for cycle-time improvement (write-time reduction and bitline precharge/discharge time reduction). The various schemes and techniques described herein may provide power savings by discharging bitlines to ground (e.g., near 0V) instead of precharging bitlines to a positive voltage supply (Vdd) for high-density bitcell memory instances. Various schemes and techniques described herein may assist with reducing write-time and reducing bitline precharge power. As such, instead of precharging bitlines to Vdd, the bitlines will be discharged to ground, such as, e.g., Gnd or Vss, which is near or equal to zero volts (0V. In some implementations, one or more or all unselected bitlines will be discharged to zero volts (0V. As such, the various schemes and techniques described herein provide for discharging the bitlines to ground (e.g., near 0V) before a read/write operation instead of precharging the bitlines to Vdd. In reference to the various implementations described herein, there is generally no area impact by introducing this circuit, and there is no critical dependency of other signals on bitline timing that may affect margin.

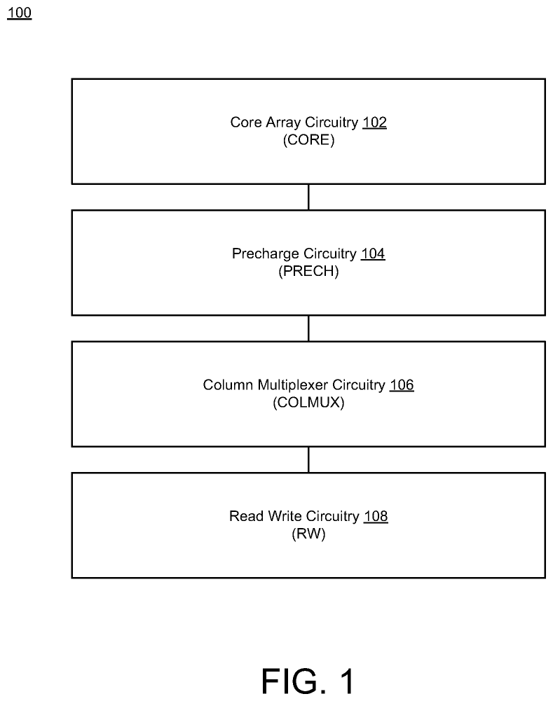

Various implementations of bitline precharge circuitry will be described in detail herein with reference to FIGS. 1-3.

FIG. 1 illustrates a block diagram of memory circuitry 100 in accordance with implementations described herein. In some instances, the memory circuitry 100 may be implemented as a system or device having various circuit components that are arranged and coupled together as an assemblage or combination of parts that provide for a memory configuration and/or form a memory type structure. Also, in some instances, a method of precharging bitlines may involve use of the various circuit components described herein to implement improved performance schemes and techniques.

As shown in FIG. 1, the memory circuitry 100 includes various components including, e.g., core array circuitry 102 (CORE), precharge circuitry 104 (PRECH), column multiplexer circuitry 106 (COLMUX) and read write circuitry 108 (RW). Further description related to the memory circuitry 100 and the various components associated therewith are described in greater detail herein below.

The memory circuitry 100 may be implemented as an integrated circuit (IC) in using various types of memory, such as, e.g., random access memory (RAM), including static RAM (SRAM), and/or any other types of volatile memory. In some instances, the memory circuitry 100 may be implemented as an IC with dual rail memory architecture and related circuitry. In other instances, the memory circuitry 100 may be integrated with computing circuitry and related components on a single chip. Also, the memory circuitry 100 may be implemented in various embedded systems for various electronic, mobile and Internet-of-things (IoT) applications, including low power sensor nodes.

As shown in FIG. 1, the memory circuitry 100 includes core array circuitry 102 (CORE) that has an array of memory cells, wherein each memory cell may be referred to as a bitcell. Also, each memory cell may be configured to store at least one data bit value (e.g., a data value related to a logical ‘0’ or ‘1’). In various instances, the array of memory cells may include any number of memory cells (or bitcells) that are arranged in various applicable configurations, such as, e.g., a two-dimensional (2D) memory array having any number of columns (Ncolumns) and any number of rows (Nrows) of multiple memory cells arranged in a 2D grid pattern with 2D indexing capabilities.

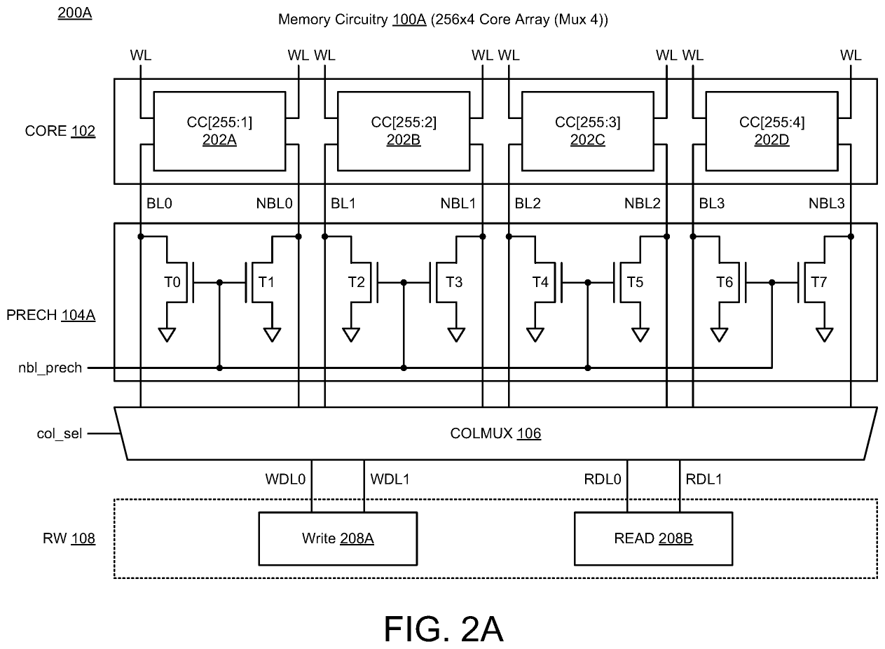

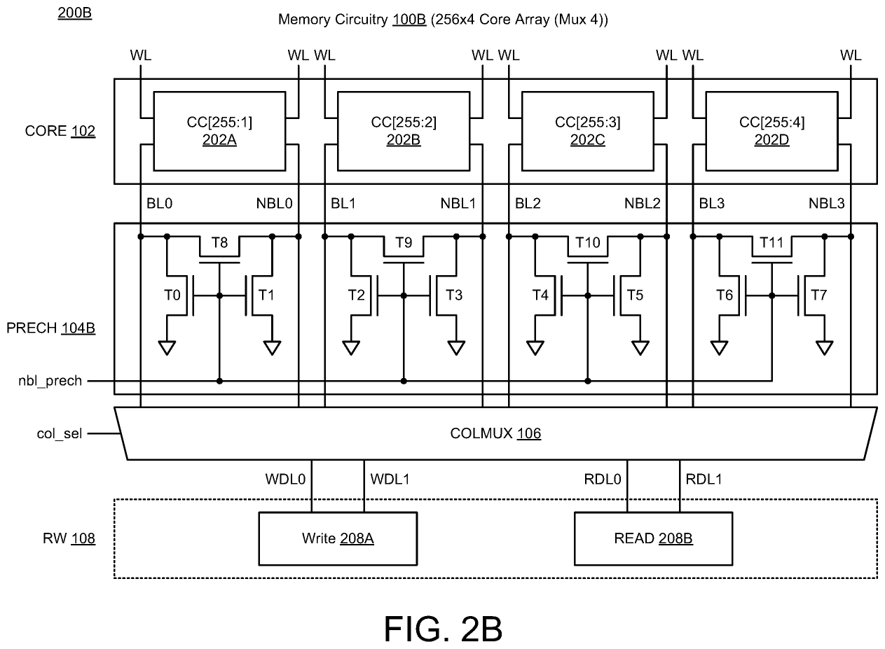

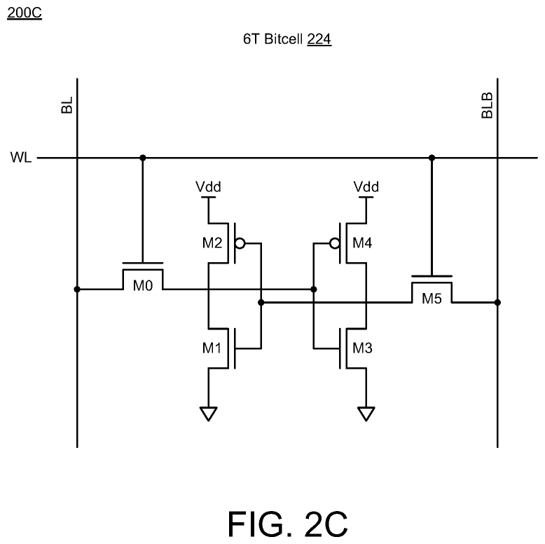

In some cases, each memory cell may be implemented with random access memory (RAM) circuitry, or some other type of volatile type memory. For instance, each memory cell (or bitcell) may include a multi-transistor static RAM (SRAM) cell, including various types of SRAM cells, such as, e.g., 6T CMOS SRAM and/or various other types of complementary MOS (CMOS) SRAM cells, such as, e.g., 2T, 4T, 8T, 10T, 12T, 14T or more transistors per bit. For reference, an example 6T CMOS SRAM bitcell 224 is shown in FIG. 2C. Also, in some instances, the memory circuitry 102 may operate at one or more source voltage levels (e.g., Vdd, Vss, etc.) with a voltage range that varies with the applicable technology for specific integrated circuits (ICs).

FIGS. 2A-2C illustrate various diagrams of the memory circuitry in accordance with various implementations described herein. In particular, FIG. 2A shows a diagram 200A of memory circuitry 100A, FIG. 2B shows a diagram 200B of memory circuitry 100B, and FIG. 2C shows a diagram of memory cell circuitry 200C.

Referring to diagram 200A of FIG. 2A, the memory circuitry 100A may include the core circuitry 102 (CORE) having an array of bitcells that are arranged in columns and rows. As shown in FIG. 2, the CORE 102 may be embodied as a Mux 4: 256x4 core array with one or more banks 202A, 202B, 202C, 202D of memory cells (or bitcells) having 256 rows of bitcells (CC[255:1], CC[255:2], CC[255:3], CC[255:4]). The CORE 102 may include a row decoder (ROWDEC) and a column decoder (COLDEC) for accessing each bitcell via a selected wordline (WL) and a selected bitline (BL, such as, e.g., BL0, NBL0, BL1, NBL1, BL2, NBL3, BL3, NBL3). The CORE 102 may include one or more bitcell arrays (e.g., banks 202A, 202B, 202C, 202D) that are accessible via a selected wordline (WL) and a selected bitline (e.g., BL0, NBL0, BL1, NBL1, BL2, NBL2, BL3, NBL3). The bitlines may be arranged in bitline pairs, wherein each bitline pair includes a first bitline and a second bitline that is a complement of the first bitline. In some instances, the CORE 102 and various components thereof may operate at a source voltage supply, such as, e.g., a core supply voltage Vdd along with ground (Gnd) at zero volts (0V or negative (−) voltage supply Vss. In other instances, voltage range may vary with technology.

The row decoder (ROWDEC) may operate at the core supply voltage Vdd, and other components, such as, e.g., a write driver may generate a write (WR) driver signal at another supply voltage that may be different than the core supply voltage Vdd, such as, e.g., the negative voltage supply Vss or some other voltage, such as, e.g., a periphery supply voltage Vddp. As described herein, the CORE 102 may operate with the following characteristics: Vdd>0V, and Gnd/Vss=0V, or near 0V.

The memory circuitry 100 may include the precharge circuitry 104A (PRECH) having one or more precharge transistor pairs (e.g., NMOS transistor pairs T0/T1, T2/T3, T4/T5, T6/T7) that are arranged in parallel and also coupled to corresponding bitline pairs (BL0/NBL0, BL1/NBL1, BL2/NBL2, BL3/NBL3). In some instances, each of the precharge transistors (T0, T1, T2, T3, T4, T5, T6, T7) may be activated based on a precharge control signal (nbl_prech). Also, each of the precharge transistors (T0, T1, T2, T3, T4, T5, T6, T7) may be coupled between the source voltage supply (Gnd or Vss) and a corresponding bitline (BL0/NBL0, BL1/NBL1, BL2/NBL2, BL3/NBL3).

In some implementations, the precharge transistors (T0, T1, T2, T3, T4, T5, T6, T7) may be referred to as switch structures that are coupled between the corresponding bitlines (BL0/NBL0, BL1/NBL1, BL2/NBL2, BL3/NBL3) and a supply voltage (e.g., Gnd or Vss). The switch structures (T0, T1, T2, T3, T4, T5, T6, T7) are configured to precharge the bitlines (BL0/NBL0, BL1/NBL1, BL2/NBL2, BL3/NBL3) to the supply voltage (e.g., Gnd or Vss) when activated by the precharge control signal (nbl_prech). In some instances, the supply voltage (Gnd or Vss) may refer to ground having a voltage near zero volts (0V, and the switch structures (T0, T1, T2, T3, T4, T5, T6, T7) are activated with the precharge control signal (nbl_prech) so as to precharge the bitlines (BL0, NBL0, BL1, NBL1, BL2, NBL2, BL3, NBL3) to ground (Gnd or Vss) after a read operation or a write operation. In other instances, the bitlines (BL0, NBL0, BL1, NBL1, BL2, NBL2, BL3, NBL3) may be precharged to ground (Gnd or Vss) before a read operation or a write operation.

In some implementations, the precharge transistors or switch structures (e.g., T0, T1, T2, T3, T4, T5, T6, T7) may include N-type transistors having drains (or drain terminals) coupled to the bitlines (BL0, NBL0, BL1, NBL1, BL2, NBL2, BL3, NBL3) and sources (or source terminals) coupled to the supply voltage (Gnd or Vss), which refers to ground (Gnd or Vss). The N-type transistors may be activated with the precharge signal (nbl_prech) coupled to a gate thereof, and thus, the N-type transistors may be activated with the precharge signal (nbl_prech) before or after a read operation or a write operation so as to precharge the bitlines to ground (Gnd or Vss).

Also, the memory circuitry 100 may include the column multiplexer circuitry 106 (COLMUX) having one or more column selector transistors that are arranged in parallel to operate as a multiplexer (Mux) and also coupled to corresponding bitlines (BL0/NBL0, BL1/NBL1, BL2/NBL2, BL3/NBL3). In some instances, the column selector transistors may be activated based on a column select control signal, and each of the column selector transistors may be coupled between the corresponding bitlines (BL0/NBL0, BL1/NBL1, BL2/NBL2, BL3/NBL3) and one or more write data lines (WDL0, WDL1) and also one or more read data lines (RDL0, RDL1). In some instances, a column selection/enable signal (col_sel) may be used to activate the column selector transistors and select one or more of the bitlines (BL0/NBL0, BL1/NBL1, BL2/NBL2, BL3/NBL3).

The memory circuitry 100 may include the read write circuitry 108 (RW) having various components that are arranged and coupled together to perform read operations and/or write operations. For instance, the read write circuitry 108 (RW) may include write circuitry 208A that is configured to perform write operations and read circuitry 208B that is configured to perform read operations. The write circuitry 208A may be coupled to the COLMUX 106 via the write data lines (WDL0, WDL1), and the read circuitry 208B may be coupled to the COLMUX 106 via the read data lines (RDL0, RDL1).

Referring to diagram 200B of FIG. 2B, the memory circuitry 100B may include similar scope, features and components, such as, e.g., the CORE 102, the COLMUX 106 and the RW 108 as the memory circuitry 100A of FIG. 2A, except for modified precharge circuitry (PRECH 104B). In some implementations, the PRECH 104B may include pass transistors (T8, T9, T10, T11) that are coupled between precharge transistor pairs (T0/T1, T2/T3, T4/T5, T6/T7), and also, the pass transistors (T8, T9, T10, T11) may be coupled between corresponding bitline pairs (BL0/NBL0, BL1/NBL1, BL2/NBL2, BL3/NBL3). For instance, as shown in FIG. 2B, pass transistor (T8) may be coupled between precharge transistors (T0, T1), pass transistor (T9) may be coupled between precharge transistors (T2, T3), pass transistor (T10) may be coupled between precharge transistors (T4, T5), and pass transistor (T11) may be coupled between precharge transistors (T6, T7). Also, the pass transistors (T8, T9, T10, T11) may be referred to as switch structures, and the pass transistors (T8, T9, T10, T11) may include N-type transistors having gates coupled to the precharge signal (nbl_prech). As such, the N-type pass transistors (T8, T9, T10, T11) may be activated with the precharge signal (nbl_prech) before or after a read operation or a write operation so as to assist with precharging the bitlines (BL0, NBL0, BL1, NBL1, BL2, NBL2, BL3, NBL3) to ground (Gnd or Vss).

In some implementations, in reference to FIGS. 2A, 2B, the memory circuitry 100A, 100B may be implemented as a system having various circuit components that are arranged and coupled together as an assemblage or combination of parts that provide for a memory configuration and/or form a memory type structure. For instance, the system may include memory circuitry 100A, 100B having multiple arrays of bitcells (banks 202A, 202B, 202C, 202D) arranged in columns and rows. The system may include multiple sets of complementary bitlines (BL0/NBL0, BL1/NBL1, BL2/NBL2, BL3/NBL3) coupled to the columns of the bitcells. The system may include wordlines (WL) coupled to the rows of the bitcells. Also, the system may include precharge circuitry 104A, 104B having multiple sets of precharge transistors (T0/T1, T2/T3, T4/T5, T6/T7) that are coupled between the complementary bitlines (BL0/NBL0, BL1/NBL1, BL2/NBL2, BL3/NBL3) and ground (Gnd or Vss). In this instance, the precharge transistors (TO/T1, T2/T3, T4/T5, T6/T7) may be configured to discharge the complementary bitlines (BL0/NBL0, BL1/NBL1, BL2/NBL2, BL3/NBL3) to ground (Gnd or Vss) when activated. As described herein, ground refers to a ground supply voltage that is equal to or near zero volts (0V).

Further, the system may include column multiplexer circuitry 106 coupled to the multiple sets of complementary bitlines (BL0/NBL0, BL1/NBL1, BL2/NBL2, BL3/NBL3), and the column multiplexer circuitry 106 may be configured to access each bitcell in the multiple arrays of bitcells (banks 202A, 202B, 202C, 202D) with a selected wordline of the wordlines (WL) and selected bitlines of the multiple sets of complementary bitlines (BL0/NBL0, BL1/NBL1, BL2/NBL2, BL3/NBL3). The system may include read and write circuitry (RW) 108 coupled to the column multiplexer circuitry 106, wherein the read and write circuitry (RW) 108 may be configured to read data from an accessed bitcell during a read operation, and wherein the read and write circuitry (RW) 108 may be configured to write data to the accessed bitcell during a write operation.

In some instances, the precharge transistors (T0/T1, T2/T3, T4/T5, T6/T7) may be activated with a precharge signal (nbl_prech) so as to precharge the complementary bitlines (BL0/NBL0, BL1/NBL1, BL2/NBL2, BL3/NBL3) to ground (Gnd or Vss) before or after a read operation or a write operation. The precharge transistors (T0/T1, T2/T3, T4/T5, T6/T7) may include N-type transistors coupled between the complementary bitlines (BL0/NBL0, BL1/NBL1, BL2/NBL2, BL3/NBL3) and ground (Gnd or Vss), and the N-type transistors may be activated with the precharge signal (nbl_prech) coupled to a gate thereof. Also, the N-type transistors may be activated with the precharge signal (nbl_prech) before or after a read operation or a write operation so as to discharge the complementary bitlines (BL0/NBL0, BL1/NBL1, BL2/NBL2, BL3/NBL3) to ground (Gnd or Vss) when activated.

FIG. 2C illustrates a schematic diagram of a memory cell 200C in accordance with implementations described herein. As shown in FIG. 2C, the bitcell 224 refers to a 6T bitcell having multiple transistors (e.g., M1, M2, M3, M4, M5, M6) that are arranged and coupled together as a memory structure. The bitcell 224 uses complementary bitlines (BL, NBL) coupled to transistors (M0, M5), and the bitcell 224 uses at least one wordline (WL) coupled to gates of transistors (M0, M5). Also, the bitcell 224 utilizes cross-coupled transistors (M1/M2 and M3/M4) that are coupled between the positive voltage supply Vdd and ground (Gnd). As shown, pass transistor (M0) may be coupled between bitline (BL) and gates of transistors (M3/M4), and pass transistor (M5) may be coupled between gates of transistors (M1, M2) and complementary bitline (NBL).

Generally, there are two types of memory structures: one-wordline devices and multi-wordline devices. In some cases, the wordline devices (e.g., ROM, DRAM, SRAM) may refer to devices having only a single access port, which may be referred to as access devices. The bitlines (e.g., BL, NBL) may be single rail or dual rail. The transistor types (e.g., NMOS and PMOS) may be referred to as access transistors.

As shown in FIG. 2C, static RAM bitcells may include a 6T bitcell, which may have access ports controlled by wordlines. In some other cases, static RAM bitcells may be implemented with a 5T bitcell, 4T 2R bitcell, or various other types of CMOS SRAM cells, such as, e.g., 8T, 10T or more transistors per bit. Further, multi-wordlines may result in multiple access ports into each of the bitcells. Since there are multiple access ports, the multi-ports access devices may be varied within each bitcell so that some access devices (by port) are NFETs and some access devices by port are PFETs. Although these may be effectively varied within each single bitcell, their number of ports may not be easily divided into equal capacitance and/or power. Thus, although these multi-ports transistor types may vary within each bitcell, there may also be a need to have a variation between arrays as in type one, such as, e.g., a left half array and a right half array.

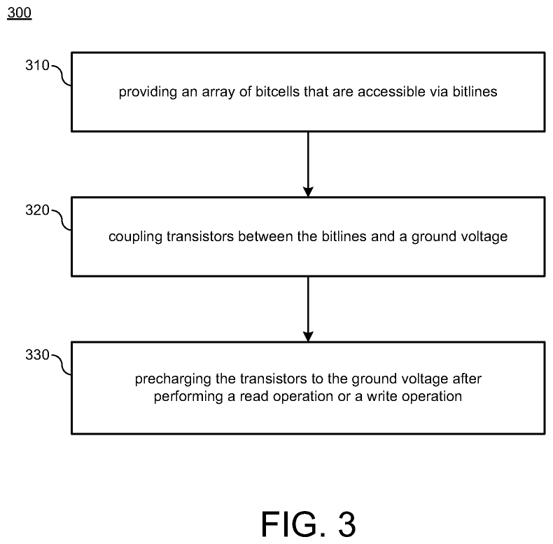

FIG. 3 illustrates a process diagram of a method 300 for providing memory circuitry in accordance with various implementations described herein.

It should be understood that even though method 300 may indicate a particular order of operation execution, in some cases, various certain portions of the operations may be executed in a different order, and on different systems. In other cases, additional operations and/or steps may be added to and/or omitted from method 300. Also, method 300 may be implemented in hardware and/or software. If implemented in hardware, the method 300 may be implemented with various circuit elements, such as described herein above in reference to FIGS. 1-2C. If implemented in software, the method 300 may be implemented as a program and/or software instruction process that may be configured for providing bitline precharge circuitry as described herein. Also, if implemented in software, instructions related to implementing the method 300 may be stored in memory and/or a database. For instance, a computer or various other types of computing devices having a processor and memory may be configured to perform method 300.

As described and shown in reference to FIG. 3, method 300 may be used for manufacturing an integrated circuit (IC) that implements bitline precharge circuitry.

As described and shown in reference to FIG. 3, method 300 may be utilized for fabricating and/or manufacturing, or causing to be fabricated and/or manufactured, an integrated circuit (IC) that implements bitline precharging schemes and techniques as described herein that are related to providing bitline precharging circuitry and/or various associated systems, devices, components and circuits.

At block 310, method 300 may provide an array of bitcells that are accessible via bitlines. In some implementations, method 300 may provide wordlines coupled to the bitcells, and each bitcell in the array is accessible via a selected wordline of the wordlines and a selected bitline of the bitlines.

At block 320, method 300 may couple transistors between the bitlines and a ground voltage. In some instances, the ground voltage refers to a voltage near zero volts (0V, and precharging the bitlines to the ground voltage refers to activating the transistors with a precharge signal. In some instances, the transistors may include N-type transistors (e.g., NMOS) having drains (i.e., drain terminals) coupled to the bitlines and sources (i.e., source terminals) coupled to the ground voltage, and the N-type transistors (e.g., NMOS) are activated with the precharge signal coupled to a gate (i.e., gate terminal) thereof.

At block 330, method 300 may precharge the transistors to the ground voltage before or after performing a read operation or a write operation. Also, the N-type transistors (e.g., NMOS) may be activated with the precharge signal before or after performing a read operation or a write operation so as to precharge the bitlines to the ground voltage.

Described herein are various implementations of a device. The device may include an array of bitcells having bitlines coupled to columns of the bitcells. The device may include switch structures coupled between the bitlines and a supply voltage, and the switch structures may precharge the bitlines to the supply voltage when activated.

Described herein are various implementations of a system. The system may include memory circuitry having multiple arrays of bitcells arranged in columns and rows. The system may include multiple sets of complementary bitlines coupled to the columns of the bitcells. The system may include wordlines coupled to the rows of the bitcells. The system may include precharge circuitry having multiple sets of precharge transistors that are coupled between the complementary bitlines and ground. The precharge transistors may be configured to discharge the complementary bitlines to ground when activated.

Described herein are various implementations of a method. The method may include providing an array of bitcells that are accessible via bitlines. The method may include coupling transistors between the bitlines and a ground voltage. The method may include precharging the transistors to the ground voltage before or after performing a read operation or a write operation.

It should be intended that the subject matter of the claims not be limited to the implementations and illustrations provided herein, but include modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. Moreover, it should be appreciated that such a development effort may be complex and time consuming, but would nevertheless be a routine undertaking of design, fabrication, and manufacture for those of ordinary skill having benefit of this disclosure.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various techniques described herein, other and further implementations may be devised in accordance with the disclosure herein, which may be determined by the claims that follow.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A device, comprising:
an array of bitcells having bitlines coupled to columns of the bitcells; and
switch structures coupled between the bitlines and a supply voltage, wherein the switch structures precharge the bitlines to the supply voltage after a write operation when activated.

2. The device of claim 1, further comprising wordlines coupled to rows of the bitcells, wherein each bitcell in the array is accessible via a selected wordline of the wordlines and a selected bitline of the bitlines.

3. The device of claim 1, wherein the supply voltage refers to a ground voltage, and wherein the switch structures precharge the bitlines to ground before a read operation and before the write operation.

4. The device of claim 1, wherein the switch structures are activated with a precharge signal so as to precharge the bitlines the supply voltage after a read operation and after the write operation.

5. The device of claim 1, wherein the bitlines comprise a first bitline and a second bitline that is a complement of the first bitline.

6. The device of claim 1, wherein the switch structures comprise N-type transistors having drains coupled to the bitlines and sources coupled to the supply voltage which refers to ground.

7. The device of claim 6, wherein the N-type transistors are activated with a precharge signal coupled to a gate thereof.

8. The device of claim 7, wherein the N-type transistors are activated with the precharge signal before a read operation or a-and before the write operation so as to precharge the bitlines to ground.

9. A system, comprising:
memory circuitry having multiple arrays of bitcells arranged in columns and rows;
multiple sets of complementary bitlines coupled to the columns of the bitcells;
wordlines coupled to the rows of the bitcells; and
precharge circuitry having multiple sets of precharge transistors coupled between the complementary bitlines and ground, wherein the precharge transistors are configured to discharge the complementary bitlines to ground after a read operation and after a write operation when activated.

10. The system of claim 9, further comprising:
column multiplexer circuitry coupled to the multiple sets of complementary bitlines, wherein the column multiplexer circuitry is configured to access each bitcell in the multiple arrays of bitcells with a selected wordline of the wordlines and selected bitlines of the multiple sets of complementary bitlines.

11. The system of claim 10, further comprising:
read and write circuitry coupled to the column multiplexer circuitry,
wherein the read and write circuitry is configured to read data from an accessed bitcell during a read operation, and
wherein the read and write circuitry is configured to write data to the accessed bitcell during a write operation.

12. The system of claim 9, wherein ground refers to a ground supply voltage.

13. The system of claim 9, wherein the precharge transistors are activated with a precharge signal so as to precharge the complementary bitlines to ground before the read operation and before the write operation.

14. The system of claim 9, wherein the precharge transistors comprise N-type transistors coupled between the complementary bitlines and ground, and wherein the N-type transistors are activated with a precharge signal coupled to a gate thereof.

15. The system of claim 14, wherein the N-type transistors are activated with the precharge signal before the read operation and before the write operation so as to discharge the complementary bitlines to ground when activated.

16. A method, comprising:
providing an array of bitcells that are accessible via bitlines;
coupling transistors between the bitlines and a ground voltage; and
precharging the transistors to the ground voltage after performing a read operation and after performing a write operation.

17. The method of claim 16, further comprising:
providing wordlines coupled to the bitcells, wherein each bitcell in the array is accessible via a selected wordline of the wordlines and a selected bitline of the bitlines.

18. The method of claim 16, wherein precharging the bitlines to the ground voltage refers to activating the transistors with a precharge signal.

19. The method of claim 16, wherein the transistors comprise N-type transistors having drains coupled to the bitlines and sources coupled to the ground voltage, and wherein the N-type transistors are activated with a precharge signal coupled to a gate thereof.

20. The method of claim 19, wherein the N-type transistors are activated with the precharge signal before performing the read operation and before performing the write operation so as to precharge the bitlines to the ground voltage.
